(19) United States
(12) Patent Application Publication
(10) Pub. No.: US 2026/0011591 A1
(43) Pub. Date: Jan. 8, 2026

(54) DEVICE FOR SUBSTRATE CONTAINERS AND METHODS OF USING THE STORAGE DEVICE

(71) Applicant: ENTEGRIS, INC., Billerica, MA (US)

(72) Inventors: Colton J. Harr, Monument, CO (US); Adam Amble, Colorado Springs, CO (US)

(21) Appl. No.: 19/263,291

(22) Filed: Jul. 8, 2025

Related U.S. Application Data
(60) Provisional application No. 63/668,680, filed on Jul. 8, 2024.

(51) Int. Cl. H01L 21/673; H01L 21/67

(52) U.S. Cl. CPC H01L 21/67393; H01L 21/67017

(57) ABSTRACT

Described are methods and apparatuses that are useful for removing contaminants from substrate containers that are used to hold, store, or transport semiconductor substrates.

### FIELD

The following description relates to methods and apparatuses that are useful for removing contaminants from substrate containers that are used to hold, store, or transport semiconductor substrates.

### BACKGROUND

During semiconductor and microelectronic device manufacturing, semiconductor substrates are processed to form microelectronic devices by performing a series of processing steps at a surface of the substrate. The steps include cleaning, material deposition, chemical processing such as photolithography, material removal such as by planarization or etching, among others, performed multiple times over a course of producing a finished microelectronic device. The presence of contaminants at the substrate surface during any of these steps will produce defects in microelectronic devices being formed on the substrate and will reduce yield.

To reduce the presence of contaminants at substrate surfaces, semiconductor substrates are processed in a highly controlled and purified atmosphere of a cleanroom or processing tool. The atmosphere is monitored and controlled to extremely high levels of purity in terms of particle contaminants and chemical contaminants, sometimes referred to as “airborne molecular contaminants,” including volatile organic compounds. Even with today's best technologies, cleanrooms and processing tools contain amounts of contaminants that are sufficient to produce defects. Airborne molecular contaminants include airborne molecular species referred to as volatile organic compounds (common examples being organic solvents such as isopropanol and acetones) as well as inorganic chemical compounds that include acid or base molecules such as ammonia (NH₃).

Between processing steps, semiconductor substrates are held in a portable substrate container that can contain multiple substrates in a sealed interior that contains a controlled atmosphere. The controlled atmosphere typically originates in a cleanroom. As substrates in the cleanroom are placed into and sealed in the substrate container, the cleanroom atmosphere also becomes enclosed in the sealed container. The cleanroom atmosphere held in the substrate container will contain a low concentration of contaminants. Additionally, substrates that are placed in the container interior from the cleanroom will have contaminants present on their surfaces. These contaminants transfer from the substrate surfaces into the gaseous atmosphere contained in the substrate container and can collect and accumulate within the substrate container.

Substrate containers are made of materials that are capable of adsorbing chemical contaminants such as those present in a cleanroom as airborne molecular contaminants or those that may be released from a surface of a substrate contained in the substrate container interior.

Substrate containers may also have contaminants that are not derived from a cleanroom environment or a substrate surface, but that are present in a material (e.g., polymer) used to manufacture the substrate container and remain present (adsorbed) in the material after the substrate container has been manufactured (these contaminants may be referred to as “resident” or “endogenous” contaminants). These resident contaminants are also considered to be “adsorbed” in the material of the substrate container, and also desorb during use of the substrate container where the desorbed contaminant may become deposited on a surface of a substrate held in the substrate container.

Decontamination tools are available to remove contaminants from substrate containers using heat, purge gas, vacuum, or a combination of these. However, this method of decontamination is expensive and inefficient. The tools are expensive, requiring the tool to achieve a significant vacuum condition. These processes are also inefficient because they are only capable of decontaminating a small number (e.g., four or fewer) of substrate containers using a batch-wise decontamination process. These processes place a small number of substrate containers within the tool and then expose the group of containers to vacuum and gas cycles. The process cannot be performed continuously by continuously moving multiple substrate containers through the tool without discrete vacuum and gas cycles.

Other decontamination techniques provide only limited effectiveness, meaning that these techniques may not remove a necessary amount of contaminants as required for semiconductor manufacturers, particularly for contaminant-sensitive processes. For example, processes of washing substrate containers may be effective to remove contaminants from container surfaces, but chemical contaminants that are adsorbed within a surface of a substrate container are located below within materials of a substrate container and are not removed by washing the surface. Other techniques can be inefficient, e.g., require significant amounts of time, such as passive techniques by which substrate containers are held at ambient conditions or a controlled atmosphere to allow adsorbed contaminants to slowly desorb from a substrate container.

Semiconductor manufacturers are careful when using substrate containers that may contain adsorbed contaminants. For substrate containers that are already in-service, semiconductor manufacturers may monitor the age of a substrate container and the amount of adsorbed contaminants in the substrate container, e.g., by measuring the rate of desorption of chemical contaminants from a substrate container before using the substrate container.

### SUMMARY

Accordingly, to address the needs of substrate container manufacturers and users, the present description introduces new equipment and methods for decontaminating substrate containers that may be more efficient (require less time), more effective (remove a greater amount of adsorbed contaminants), and are less expensive than previous decontamination methods.

Decontamination apparatuses as described are effective to remove contaminants from substrate containers by placing the substrate containers in an enclosure that contains a clean environment that causes adsorbed contaminants to be released (desorbed) from the substrate containers. Airborne molecular contaminants will adsorb or desorb from a substrate container material to reach equilibrium with a surrounding clean environment following the concepts of Henry's Law. Adsorbed contaminants will diffuse through a material of a substrate container according to Fick's first law of diffusion. A material of a substrate container in a clean environment (decontaminating atmosphere) will desorb adsorbed contaminants until the amount of adsorbed contaminants reaches equilibrium with the clean environment. The optimal time to use a substrate container in sensitive manufacturing processes is after the substrate container has reached equilibrium with a clean environment and therefore adsorbs contaminants from the environment rather than desorbing contaminants into the interior of the substrate container.

According to example decontamination methods and decontamination apparatuses, a substrate container is contained in a gaseous “decontaminating atmosphere” that is contained within an interior of a decontamination apparatus (an “apparatus interior”). The decontaminating atmosphere can be defined in terms of conditions (“decontamination conditions”) that cause desorption of adsorbed contaminants, including conditions of pressure, temperature, a concentration of one or more different contaminants (e.g., concentration of airborne molecular contaminants such as volatile organic compounds), and humidity. These decontamination conditions, individually or in combination, cause contaminants that are adsorbed in a material of a substrate container to be desorbed and removed from the material.

More specifically, per the present description, these decontamination conditions will cause the absorbed contaminants to desorb from the material at a rate that is faster than a rate at which the adsorbed contaminants desorb from the material when the material is held in an atmosphere at the exterior of the decontaminating apparatus. According to examples processes, a temperature of the decontaminating atmosphere can be higher than a temperature of the exterior atmosphere, the pressure of the decontaminating atmosphere may be lower than the pressure of the exterior atmosphere, the relative humidity of the decontaminating atmosphere may be different from (higher or lower than) the exterior atmosphere, the concentration of one or more contaminants in the decontaminating atmosphere, particularly airborne molecular contaminants, can be less than the concentration of the one or more contaminants in the exterior atmosphere.

A decontamination apparatus has one or more access ports that allow substrate containers to be transferred directly between an exterior atmosphere and a decontamination atmosphere having the decontamination conditions. This advantageously allows the decontamination apparatus to perform decontamination processes on multiple substrate containers held at the apparatus interior, while other substrate containers are moved between the exterior atmosphere and the decontaminating atmosphere. Example decontamination processes can be performed in a relatively stable decontaminating atmosphere having relatively stable decontamination conditions, and without the need to cycle a decontaminating pressure between atmospheric pressure and a significant vacuum condition, e.g., a pressure below 1 millibar.

The pressure of the decontaminating atmosphere may be maintained at a relatively stable pressure that is above a low vacuum pressure during a decontamination process, e.g., in a range from above 1, 10, or 100 millibar. For example, with a decontaminating atmosphere having a pressure of at least 1, 10, or 100 millibar, e.g., above 0.2, 0.5, 0.8, or 0.9 atmosphere, the decontaminating atmosphere may hold multiple substrate containers for decontamination periods at the apparatus interior, during which decontamination periods other substrate containers are transferred between the decontaminating environment at the apparatus interior and an exterior atmosphere that has one or more different conditions of pressure, temperature, humidity, or concentration of airborne molecular contaminants. Substrate containers can be loaded and unloaded into the decontaminating atmosphere without interrupting a decontamination process of another substrate container that is held in the decontaminating atmosphere, and while the pressure of the decontaminating atmosphere remains relatively stable at a level that is above a low vacuum pressure.

A decontamination apparatus may include optional monitoring and control systems that are adapted to control decontamination processes of multiple substrate containers, to circulate and optionally recycle a decontaminating atmosphere, or to conserve energy or filter life when a target condition of a decontaminating atmosphere is achieved. Controls may include any one or combination of the following:
Maintaining an elevated temperature of a decontaminating atmosphere to accelerate a rate of desorption and outgassing of adsorbed contaminants.
Vacuum pressure to accelerate a rate of desorption and outgassing of adsorbed contaminants.
Chemical filtration to capture and remove airborne molecular contaminants from a decontaminating atmosphere, which may be optionally filtered and re-introduced (re-cycled or re-circulated) as a clean decontaminating gas.
Particle filtration using a particle filter, e.g., by HEPA or ULPA filtration, with optional recycling or re-circulation in the decontaminating atmosphere.
Humidity control to control humidity of a decontaminating atmosphere and remove moisture from a substrate container or to accelerate or decelerating a rate of diffusion or desorption of an adsorbed contaminant.
Ventilation and circulation of a decontaminating atmosphere for drawing in clean decontaminating gas having a low concentration of contaminants and exhausting decontaminating atmosphere as an effluent having a high concentration of contaminants.

According to one aspect, the description relates to a method of decontaminating a substrate container. The method includes: in a decontamination apparatus that comprises an enclosure that defines an apparatus interior, an access port that connects the apparatus interior to an exterior atmosphere, and decontaminating atmosphere in the apparatus interior; moving a substrate container from the apparatus exterior, through the access port, and into the decontaminating atmosphere, the substrate container comprising a body that contains adsorbed contaminants, the decontaminating atmosphere causing the absorbed contaminants to desorb from the body at a rate that is faster than a rate at which the adsorbed contaminants desorb from the body when held in the exterior atmosphere.

In another aspect, the description relates to a decontamination apparatus for decontaminating a substrate container. The decontamination apparatus includes: an enclosure that defines an apparatus interior; an access port that connects the apparatus interior to an exterior atmosphere; decontaminating atmosphere in the apparatus interior, the decontaminating atmosphere being capable of causing adsorbed contaminant present in a material of a substrate container to desorb from the material at a rate that is faster than a rate at which the adsorbed contaminant desorbs from the material when held in the exterior atmosphere; the access port being adapted to allow a substrate container to be moved between the exterior atmosphere and the decontaminating atmosphere.

### BRIEF DESCRIPTION OF THE FIGURES

FIG. 1 shows an example of a substrate container for use with decontamination methods as described.

FIG. 2 shows an example decontamination apparatus and methods.

FIG. 3 shows an example decontamination apparatus and methods.

FIG. 4 shows an example decontamination apparatus and methods.

FIG. 5 shows an example decontamination apparatus and methods.

All drawings are schematic and not to scale.

### DETAILED DESCRIPTION

Described as follows are decontamination apparatuses and methods that are effective to decontaminate a substrate container, meaning to remove an amount of contaminants from one or more substrate containers. A substrate container (or simply a “container” as used herein) includes a container body (sometimes referred to as a “shell”) that has an interior, an opening on one side of the container body to access the interior, and a door that is adapted to cover the opening to enclose and seal the interior. The container will typically also include one or more inlet ports to allow gas to be added to the container interior and one or more outlet ports to allow gas to be removed from the container interior, such as for filling the container interior with a gas or removing gas from the container interior, e.g., to purge the container interior with a purge gas.

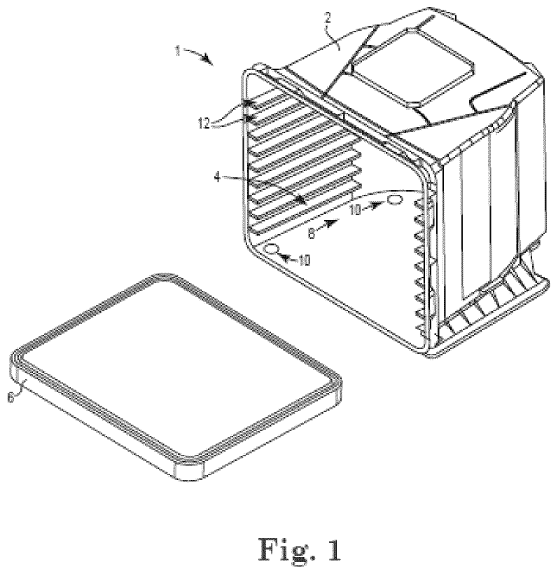

An example of a substrate container is shown at FIG. 1. FIG. 1 shows a substrate container that can be processed according to a decontamination process and using a decontamination apparatus as described. Substrate container 1 includes container body (e.g., “shell”) 2, front opening 4, interior 8, ports (inlets our outlets) 10 in the form of openings that pass through the bottom wall of body 2, and slots 12 at opposite interior sidewalls to support multiple substrates. Slots 12 are individually adapted to engage and support edges of a substrate (not shown) as multiple substrates are held within interior 8. Substrate container 1 also includes door 6, which can be used to cover opening 4 to close and seal interior 8.

Substrate container 1 can be used for transporting, containing, or storing substrates (e.g., semiconductor wafers) that are being processed by a series of processing steps (i.e., substrates that are “in-process”), between steps of the series. Substrate container 1 can include a standard mechanical interface (SMIF) of a type known for use with semiconductor processing equipment. As illustrated at FIG. 1, container 1 is a front opening container, for example, a “front opening unified pod” or “FOUP.”

Contaminants may be present at surfaces of a substrate container based on the processing history of the substrate container and based on the use history of the substrate container. Contaminants from multiple different sources may be present in a substrate container.

One type of contaminant is referred to as “resident contaminants” or “endogenous contaminants.” Substrate containers are prepared from materials, e.g., polymeric materials such as plastics, that contain small amounts of chemical contaminants that are present in the material as the substrate container is manufactured. These types of contaminants include low molecular weight chemical molecules such as unreacted monomers, oligomers, solvents, plasticizers, metal catalyst, etc. After manufacturing, amounts of these contaminants remain present as adsorbed contaminants in the material and are released from the material over time, for example into a gaseous atmosphere of a substrate container interior that also contains one or more substrates. The desorbed contaminants become airborne molecular contaminants (e.g., “volatile organic compounds”) within the container interior.

Examples of resident contaminants include organic or inorganic chemical molecules such as unreacted monomers of a polymeric material of a semiconductor container structure (including dimers or oligomers), plasticizers, organic solvents, and metal ions and metal-containing compounds used as catalysts, among others. Particular chemical species may include polycarbonates, reactive but unreacted monomers or dimers or oligomers, methyl-ethyl ketone (MEK), isopropyl alcohol (IPA), sulfur dioxide (SO₂), acetone, propylene glycol methyl ether acetate (PGMEA), aromatic compounds such as toluene and others, aliphatic hydrocarbon molecules, alcohols, ammonia (NH₃), as well as other relatively low molecular weight non-polymeric chemical materials of a container structure that are used for preparing the structure but are not a component of the polymeric material and are capable of evolving and being released from the material over time.

Decontamination apparatuses and methods as described can be effective to remove resident contaminants from a material of a substrate container and reduce an amount of one or more resident contaminants in the material to a desirably low concentration. In particular examples, a process of decontaminating a substrate container may be effective to reduce a concentration of any one or more resident contaminants (e.g., a particular species of airborne molecular contaminant or volatile organic contaminant) in a material of a substrate container to a desirably low level as measured by a rate of desorption (or “desorption rate”) of one or more resident contaminants from a material of a substrate container. Methods of measuring desorption rates of adsorbed contaminants are known and can be performed using commercially available equipment.

Other contaminants that may be present at a substrate container interior include those referred to as “exogenous contaminants.” Exogenous contaminants are not “resident contaminants” that are residual chemicals present in a material of a substrate container during and following manufacturing, but are introduced to a substrate container surface during use from an exogenous source and then accumulate at and optionally are adsorbed by a surface of the substrate container.

Exogenous contaminants include chemical and particle contaminants that are initially present in an atmosphere in which the substrate container is used, e.g., a cleanroom or other location of a substrate container. Exogenous contaminants also include chemical and particle contaminants that are initially present at a surface of a substrate that is placed and held within a substrate container. During use of a substrate container, these exogenous contaminants will become present in a substrate container interior as part of a container atmosphere and then become deposited at interior surfaces of the substrate container. These exogenous particle and chemical contaminants may accumulate at interior surfaces of the substrate container. Airborne molecular contaminants, including volatile organic contaminants, will also diffuse into the surface of the material, e.g., become adsorbed at a surface of a material of the substrate container. When these contaminants are present in a gas such as a decontaminating atmosphere, these contaminants are referred to as “airborne molecular contaminants,” e.g., “volatile organic compounds.” When these contaminants are present at a surface or adsorbed at a surface of a material of a substrate container, they are referred to as “adsorbed chemical contaminants.”

Examples of exogenous contaminants include both particle contaminants and chemical contaminants (volatile organic compounds, airborne molecular contaminants) such as organic or inorganic chemical molecules. Specific examples include organic and inorganic molecules that may be used as a solvent, a base, or an acid during a process used to manufacture a semiconductor device. Certain specific examples include organic and inorganic acid molecules; sulfur compounds; base molecules; amine compounds such as organic amines and silyl amines, organic compounds such as alcohols (isopropyl alcohol), acetones, and other low molecular weight organic solvents; ammonia (NH₃); sulfur dioxide (SO₂); ethyl acetate (EA); hydrogen fluoride (HF); methyl-ethyl ketone (MEK); propylene glycol monomethyl ether (PGME); propylene glycol methyl ether acetate (PGMEA); aromatic hydrocarbons such as toluene; as well as others.

Decontamination apparatuses and methods as described can be effective to remove non-resident or “exogenous” contaminants from a substrate container and reduce the amount of exogenous contaminants in a substrate container to a desirably low amount. During a decontamination step, exogenous contaminants that are deposited or adsorbed at surfaces of a substrate container can be removed from the substrate container. According to certain example methods, a process of decontaminating a substrate container may be effective to reduce a concentration of any one or more exogenous contaminants (e.g., a particular species of airborne molecular contaminant or volatile organic contaminant) in a material of a substrate container to a desirably low level, as measured by desorption rate.

According to example decontamination processes and decontamination apparatuses, one or multiple substrate containers are held in a gaseous decontaminating atmosphere contained at an interior of a decontamination apparatus (an “apparatus interior”). The decontaminating atmosphere has a pressure, a temperature, a concentration of one or more different contaminants (e.g., concentration of airborne molecular contaminants such as volatile organic compounds), and a humidity that, individually or in combination, cause adsorbed contaminants to be desorbed and removed from the material. According to example apparatuses and methods, the decontaminating atmosphere will cause absorbed contaminants to desorb from the material at a rate that is faster than a rate at which the adsorbed contaminants desorb from the material when the material is held in the exterior atmosphere. The decontaminating atmosphere can cause a faster rate of desorption of adsorbed contaminants compared to a rate of desorption of the contaminants if held in the exterior atmosphere.

A useful temperature of a decontaminating atmosphere may be any temperature that in combination with other conditions of a decontaminating atmosphere is effective to cause desorption of adsorbed contaminants, e.g., a temperature in a range from ambient (e.g., 32 degrees Celsius) to 50 or 100 degrees Celsius.

A useful level of relative humidity of a decontaminating atmosphere may be any relative humidity that in combination with other conditions of a decontaminating atmosphere is effective to cause desorption of adsorbed contaminants, e.g., a relative humidity in a range from 10 to 80 percent.

A useful concentration of airborne molecular contaminants in a decontaminating atmosphere may be any concentration that, in combination with other conditions of a decontaminating atmosphere, is effective to cause desorption of adsorbed contaminants. Concentrations of airborne molecular contaminants can be measured individually for multiple different contaminants, including different airborne molecular contaminants. According to useful methods, a concentration of one or more airborne molecular contaminants in a decontaminating atmosphere may be below 200 parts per billion (ppb), e.g., less than 100 ppb, or less than 50 ppb.

During use, one or multiple substrate containers are transferred into an apparatus interior and held within the decontaminating atmosphere for a period of time (a “decontamination period”) that is effective to remove an amount of adsorbed contaminant from a material of the substrate container. Optionally, a substrate container may be held for storage in the apparatus interior following the decontamination period, referred to as a “storage period,” then removed from the apparatus interior. A process that includes moving a substrate container from an apparatus exterior into the apparatus interior, holding the substrate container in the apparatus interior for a decontamination period and optional storage period, and then removing the substrate container from the apparatus interior, is referred to as a “decontamination process.”

During a decontamination process, the decontaminating atmosphere can have a concentration of one or more airborne molecular contaminants, e.g., volatile organic compounds, that is sufficiently low to cause adsorbed contaminants in a material of a substrate container to diffuse and desorb from the material. The decontaminating atmosphere may also be controlled to have a pressure, temperature, and relative humidity that will cause removal (e.g., diffusion and desorption) of adsorbed contaminants from one or more substrate containers held in the apparatus interior.

The term “decontaminating atmosphere” refers to the gaseous atmosphere contained in an apparatus interior during a decontamination process. The one or more substrate containers will contain contaminants that transfer from the one or more substrate containers into the decontaminating atmosphere. Contaminants that are removed from the substrate container during a decontamination process are transferred to the decontaminating atmosphere, which will cause an increase in the amount of contaminants in the decontaminating atmosphere.

During a decontaminating process, to maintain an effective concentration of contaminants in the decontaminating atmosphere and to prevent accumulation of contaminants in the decontaminating atmosphere, the decontaminating atmosphere may be cleaned, e.g., using a contaminant removal device. Alternately, or additionally, a portion of the decontaminating atmosphere can be continuously or intermittently removed (as “effluent”) and replaced by adding clean decontaminating gas to the apparatus interior. For example, a portion of decontaminating atmosphere in the apparatus interior may be continuously or intermittently caused to flow out of the apparatus interior as effluent, and clean decontaminating gas may be intermittently or continuously added to the apparatus interior.

“Clean decontaminating gas” may be any gas that contains a desirably low amount (concentration) of airborne molecular contaminants, e.g., a low concentration of one or more species of volatile organic compounds. A clean decontaminating gas may be or may contain one or more of: gas of an exterior atmosphere, e.g., an atmosphere of a clean room which may be optionally filtered to remove particle or chemical contamination; “recycled decontaminating atmosphere”; purified air; clean dry air; a clean and dry inert gas; or another gas that contains a low concentration of one or more airborne molecular contaminants (e.g., volatile organic compounds) and optionally a low moisture content (e.g., relative humidity).

A clean decontaminating gas can have a low concentration of one or more airborne molecular compounds, e.g., a measured concentration of any one or more airborne total molecular contaminants, individually or in total, that is below 200 parts per billion (ppb), e.g., less than 100 ppb, or less than 50 ppb.

During the decontamination process, the pressure of the decontaminating atmosphere within the apparatus interior (the “decontaminating atmosphere pressure”) can be maintained within a range that is effective to cause desorption of adsorbed contaminants from a material of a substrate container but is not required to be lower than a “low vacuum” pressure, e.g., below 1 millibar. Example decontamination processes do not require a pressure below a low vacuum level, and also do not require the pressure of the decontaminating atmosphere to be cycled between a low vacuum pressure and a higher pressure, e.g., atmospheric pressure. Useful decontamination processes can be performed in a decontaminating atmosphere having a pressure that is greater than low vacuum pressure, up to about atmospheric pressure. Example decontaminating atmosphere pressures may at least 1, 10, or 100 millibar, e.g., at least 0.2, 0.3, or 0.5 atmosphere, and up to about atmospheric pressure, such as up to 0.8, 0.9, 1.0, or 1.1 atmosphere.

According to example decontamination processes, the decontaminating atmosphere may be held at a relatively stable pressure during a decontaminating process. A “relatively stable” decontaminating atmosphere pressure refers to a pressure of a decontaminating atmosphere, measured at the apparatus interior, that remains approximately the same or within a specified range during one or more steps of a decontamination process e.g.: the decontaminating atmosphere pressure when a substrate container is transferred into the apparatus interior is approximately equal to the decontaminating atmosphere pressure during the decontamination period of the substrate container, which is approximately equal to the decontaminating atmosphere pressure when the substrate container is removed from the apparatus interior. In example decontamination processes, a relatively stable pressure of a decontaminating atmosphere may be a pressure that does not vary by more than 0.3, 0.2, 0.1, or 0.05 atmosphere.

Maintaining a relatively stable decontaminating atmosphere at the apparatus interior during decontamination processes of multiple substrate containers allows the apparatus to decontamination multiple substrate containers using a continuous or semi-continuous process. Individual substrate containers may be processed through the decontamination apparatus without interrupting the decontaminating process to significantly change the decontaminating atmosphere pressure to facilitate desorption of adsorbed contaminants. Multiple substrate containers may be loaded and unloaded into the apparatus interior continuously and each substrate container can be held within the decontaminating atmosphere during a decontamination period that is different for different substrate containers.

One or more access ports allow a substrate container to be moved between the apparatus interior and the apparatus exterior without requiring the exterior atmosphere and the interior atmosphere to be equalized. A decontamination process can be performed without cycling the decontaminating atmosphere pressure between a relatively higher pressure for loading and unloading, and a lower pressure for a decontamination period.

Instead, the pressure at the apparatus interior can remain relatively stable as multiple substrate containers are moved into the apparatus interior, held in the apparatus interior for a decontamination period, and then removed from the apparatus interior. Multiple decontamination processes can be performed on multiple substrate containers, e.g., continuously or semi-continuously, without requiring the decontaminating atmosphere pressure to be deliberately cycled for loading and unloading. Each substrate container can be held in the apparatus interior for a decontamination period that is specific to the individual substrate container, and each substrate container can be removed individually as needed, e.g., sequentially and optionally but not necessarily in the same order in which the individual substrate containers were transferred into the apparatus interior. While an individual substrate container is held during a decontamination period, other substrate containers are removed from the apparatus interior, while still other substrate containers are loaded into the apparatus interior, with relatively stable pressure at the apparatus interior. The apparatus interior may contain approximately a steady total number of substrate containers being decontaminated or stored, e.g., an apparatus interior may contain at least 5, 10, 15, 20, or more substrate containers for decontamination, while individual substrate containers are continuously loaded into and unloaded from the apparatus interior.

An individual substrate container may be removed (“unloaded”) from the apparatus interior after a decontamination period. The decontamination period may be sufficient to remove a desired amount of adsorbed contaminants from a substrate container and may be measured as a period of time or based on a measured amount of adsorbed contaminants in a substrate container.

According to example methods, an individual substrate container may be held in a decontaminating atmosphere at an apparatus interior for a time that is sufficient to reduce an amount of one or more adsorbed contaminants in the substrate container to an amount that is in equilibrium with a concentration of the contaminant in the decontaminating atmosphere.

Additionally or alternately, an individual substrate container may be held in a decontaminating atmosphere at an apparatus interior for a time that is sufficient to reduce an amount of one or more adsorbed contaminants in the substrate container to an amount that less than 50, 60, or 70 percent of an amount of the one or more adsorbed contaminants in the substrate container before the substrate container is loaded into the apparatus interior, as measured by a desorption rate of the one or more adsorbed contaminants from the substrate container.

Additionally or alternately, an individual substrate container may be held in a decontaminating atmosphere at an apparatus interior for a time that is sufficient to reduce an amount of total volatile organic compounds in the substrate container to an amount that less than 1,000, e.g., less than 750 parts per billion (volume)(ppbv), as measured by a desorption rate of the one or more adsorbed contaminants from the substrate container.

Additionally or alternately, an individual substrate container may be held in a decontaminating atmosphere at an apparatus interior for an amount of time (e.g., a decontamination period and optional storage period) that is considered sufficient to reduce an amount of one or more adsorbed contaminants in the substrate container to a desired amount, e.g., for a time period of up to or greater than 1, 2, 3, 4, or 5 days.

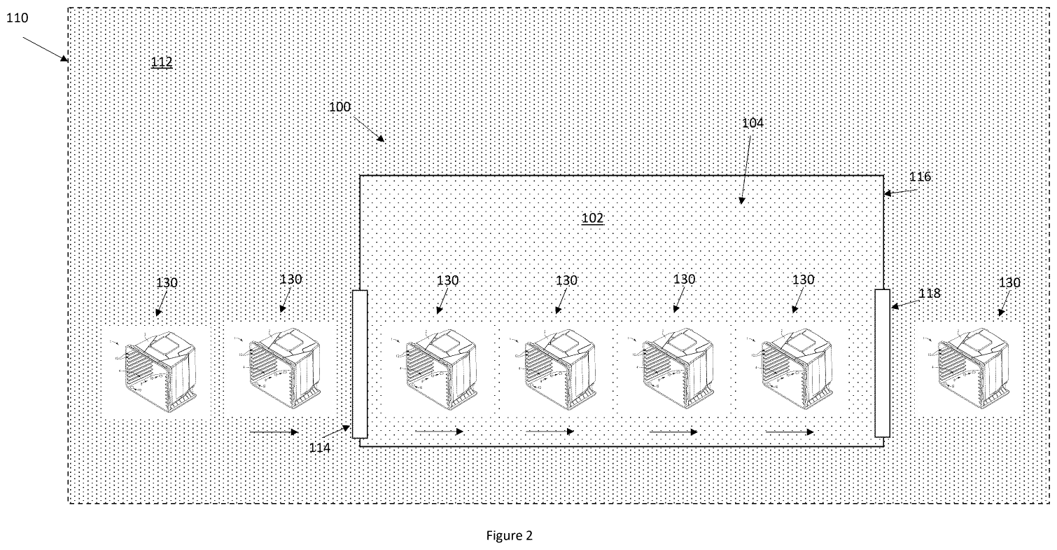

Referring to FIG. 2, illustrated is example decontamination apparatus 100 being used to decontaminate multiple substrate containers 130, continuously and sequentially, while a pressure within an apparatus interior is maintained to be above a low vacuum pressure, which may be relatively stable. Decontamination apparatus 100 includes enclosure 116 that includes a top, a bottom, and sidewalls that enclose apparatus interior 104 that contains decontaminating atmosphere 102. Decontamination apparatus 100 is housed in a larger space, referred to as apparatus exterior 110, which contains exterior atmosphere 112. Decontaminating atmosphere 102 has one or more decontamination conditions (pressure, temperature, relative humidity, and concentration of one or more airborne molecular contaminants) that individually or in combination cause one or more absorbed contaminants to desorb from a substrate container (130) at a rate that is faster than a rate at which the one or more adsorbed contaminants desorb from the substrate container (130) when held in exterior atmosphere 112.

Access ports 114 and 118 are openings through sidewalls of apparatus 100 that allow a substrate container 130 to be moved between exterior atmosphere 112 of apparatus exterior 110 and apparatus interior 104 containing decontaminating atmosphere 102. Substrate containers 130 are depicted as only the body of a substrate container but should be considered to optionally represent an entire substrate container that includes the body and other components that include a door, one or more gaskets, and other structures.

During a process of decontaminating the multiple substrate containers 130, each substrate container 130 is first moved from apparatus exterior 100 into apparatus interior 104 through access port 114. Each individual substrate container 130 is held within decontaminating atmosphere 102 for a decontamination period and an optional storage period, and subsequently removed through access port 118. During these steps, including steps of moving each substrate container 130 through access port 114 and access port 118, the pressure of decontaminating atmosphere 102 at apparatus interior 104 can be held at above a low vacuum pressure, which may be a relatively stable pressure as described herein. As each substrate container is held in apparatus interior 104 for a decontamination period, one or more other substrate containers 130 can be removed from apparatus interior 104 through access port 118, while one or more substrate containers 130 can be loaded into interior 104 through access port 114. These steps of multiple decontamination processes for multiple substrate containers 130 can be performed continuous or semi-continuous with the pressure at apparatus interior 104 being held above a low vacuum pressure, e.g., a relatively stable pressure, as each substrate container is loaded or unloaded into apparatus interior 104 through access port 114 or access port 118.

As shown at FIG. 2 and further described, a decontamination apparatus can include an enclosure that includes a top (e.g., a ceiling or another upper boundary), a bottom (e.g., a floor or another lower boundary), and sidewalls that together define an apparatus interior. The decontamination apparatus also includes one or more access ports that connect the apparatus interior to an apparatus exterior to allow loading and unloading of substrate containers between the decontaminating environment of the apparatus interior and the exterior environment of the apparatus exterior. The enclosure can be of a type that effectively seals and separates the decontaminating atmosphere from the exterior atmosphere other than at the one or more access ports. The sidewalls, top, bottom, and seams between them may preferably be effective to prevent interchange of the decontaminating atmosphere with the exterior atmosphere at those portions of the enclosure. A useful or preferred enclosure may be capable achieving a pressure at the apparatus interior of 0.5, 0.3, or 0.1 atmosphere, and maintaining that pressure using one or more vacuum pumps while performing decontamination processes on one or more substrate containers.

The exterior of the decontamination apparatus (referred to as a “apparatus exterior” or simply “exterior”) is a space (“exterior space”) that surrounds at least a portion of the decontamination apparatus, e.g., is adjacent to one or more of the sidewalls and top. The exterior space need not surround the entire decontamination apparatus but is located with one or more access ports being connected to the exterior atmosphere to allow a substrate container to be transferred from the exterior atmosphere, through the access port, and into the decontaminating atmosphere of the apparatus interior.

The apparatus exterior may be any space that can be a useful location of a decontamination apparatus for decontaminating one or more substrate containers. Examples include a clean room, a location for storing substrate containers such as a warehouse or a semiconductor manufacturing facility, a clean space of a location where substrate containers are manufactured and may be processed to decontaminate substrate containers, or any other location for storing, staging, or decontaminating one or more substrate containers. The exterior space may be a relatively clean space with a relatively pure or clean exterior atmosphere. Example exterior atmospheres may have a low concentration of airborne molecular contaminants (including volatile organic compounds), particle contaminants, or both. Example exterior atmospheres may be that of a relatively clean cleanroom or warehouse having an ISO rating of ISO-1, ISO-2, ISO-3, ISO-4, ISO-5, ISO-6, ISO-7, ISO-8, or ISO-9.

The decontaminating atmosphere may be circulated through the apparatus interior and maintained at a desired pressure, temperature, relative humidity, and contaminant concentration by a circulation system. Example circulation systems can continuously or intermittently (e.g., periodically) introduce clean decontaminating gas into the apparatus interior through an apparatus inlet, and continuously or intermittently remove decontaminating atmosphere (which contains contaminants removed from one or more substrate containers during a decontamination process) from the apparatus interior through an apparatus outlet as an effluent.

A circulation system can include flow control devices such one or more fans, heaters, humidifier, vacuum pumps, flow conduits, etc., to control the flow, pressure, temperature, or relative humidity of a decontaminating atmosphere at the apparatus interior. Optionally, the circulating system can include a contaminant removal device that removes one or more contaminants from the decontaminating atmosphere or an effluent. The effluent may be processed by a contaminant removal device and optionally re-introduced to the apparatus interior as a clean decontaminating gas (i.e., “recycled decontaminating gas”).

According to certain examples, a clean decontaminating gas can be introduced into the apparatus interior, passed through the apparatus as a decontaminating atmosphere, and removed from the apparatus interior as an effluent without being recirculated or returned to the apparatus interior as recycled decontaminating gas. This method of circulating the decontaminating gas through the apparatus interior can be referred to as a “single pass” or “pass through” method. These example methods can process the decontaminating atmosphere using a contaminant removal device located within the apparatus interior. Alternate example methods can process the effluent using a contaminant removal device to remove contaminants from the effluent and return the processed effluent to the apparatus interior as recycled decontaminating gas.

A contaminant removal device can by any type of material or device that is effective to remove one or more particle or chemical contaminants (e.g., volatile organic compounds) from a decontaminating atmosphere located at an apparatus interior being removed from the apparatus interior at effluent. Examples include adsorbents, oxidizers (thermal oxidizers, catalytic oxidizers), and particle filters (e.g., “HEPA” filters, meaning high efficiency particulate air filters). In some examples, the contaminant removal device may include adsorbent that can be effectively regenerated, such as by exposing the adsorbent to elevated temperature to remove adsorbed contaminants.

Useful examples of adsorbents include activated carbons, metal organic frameworks (MOF), zeolites such as zeolite imidazole frameworks (ZIFs), ion exchange resins, silicas, molecular sieves, and other adsorbent materials that are useful to volatile organic compounds. Many varieties of each of these types of adsorbents are known and commercially available. Other contaminant removal devices include filters that are adapted to remove particle contaminants from a decontaminating atmosphere or effluent.

The enclosure includes one or more access ports that connect the apparatus interior to the apparatus exterior and allow movement of a substrate container between the apparatus exterior and the apparatus interior. Multiple access ports may be used to allow for multiple substrate containers to be moved between the apparatus interior and the apparatus exterior sequentially or simultaneously, for example with one or multiple access ports being used to move substrate containers from the apparatus exterior into the apparatus interior, and a one or more additional access ports adapted to move substrate containers from the apparatus interior to the apparatus exterior.

An access port may generally be any opening that allows movement of a substrate container between the apparatus exterior and the decontaminating atmosphere at the apparatus interior, such as a door or opening that can optionally be opened and closed. A useful or preferred access port may be adapted to move a substrate container between the apparatus interior and the apparatus exterior without requiring the pressure at the apparatus exterior and the pressure at the apparatus interior to be equalized, and without requiring the pressure at the apparatus interior to be changed or adjusted. Example access ports may inhibit or prevent mixing of the decontaminating atmosphere and the exterior atmosphere as a substrate container is moved between the apparatus interior and the apparatus exterior, to prevent contamination of the decontaminating atmosphere by the exterior atmosphere. An access port may be of a type that can be sealed or substantially sealed when closed to prevent mixing of the interior atmosphere and the exterior atmosphere when closed.

An example access port may include an “airlock” that allows a substrate container to be moved between the decontaminating atmosphere and the exterior atmosphere having significantly different pressure conditions. An airlock may include a transfer chamber between the apparatus interior and the apparatus exterior that is connected to both the exterior atmosphere and the decontaminating atmosphere by a first sealable portal and a second sealable portal. The airlock allows a substrate container to pass through the first sealable portal from the exterior atmosphere at a higher pressure condition (e.g., atmospheric pressure), into the transfer chamber. The two sealable portals of the transfer chamber are then closed and the pressure within the transfer chamber is reduced to a lower pressure (e.g., a vacuum pressure) of the decontaminating atmosphere at the apparatus interior. The second sealable portal is then opened and the substrate container can be moved into the apparatus interior. An airlock with a transfer chamber may be useful with an access port to moved substrate containers between an apparatus exterior that is at approximately atmospheric pressure, and an apparatus interior that is under vacuum, e.g., having a pressure that is below 0.9 atmosphere.

Another example access port may include a “cascade airlock” that allows a substrate container to be moved between an apparatus exterior that is at approximately atmospheric pressure and an apparatus interior that is slightly above the pressure at the apparatus exterior but still approximately atmospheric pressure, e.g., the pressure at the apparatus interior may be at least 0.05 or 0.1 millibar greater than the pressure at the apparatus exterior.

A decontamination apparatus may include, at the apparatus interior, a device or system (“conveyor”) that moves a substrate container between locations within the apparatus interior, either horizontally or vertically, or both, e.g., to allow for one-dimensional (e.g., linear, horizontal or vertical), two-dimensional (e.g., in two or more horizontal or vertical directions) or three-dimensional (in two horizontal directions and vertically) movement of a substrate container within the apparatus interior. An example conveyor may move a substrate container vertically, horizontally, or both, during a decontamination period and optional storage period.

The decontamination apparatus can include a control system that includes or is connected to one or more different types of sensors and operating mechanisms that are used to operate and control the decontamination apparatus and decontamination processes of multiple substrate containers. One or more sensors may include sensors adapted to detect and measure a concentration of one or more airborne molecular contaminant (e.g., volatile organic compounds) in a decontaminating atmosphere, temperature at an apparatus interior, pressure at an apparatus interior, humidity at an apparatus interior, and one or more flows of gas within the apparatus interior or between the apparatus interior and apparatus exterior.

A sensor that measures a concentration of airborne molecular contaminants or volatile organic compounds in a decontaminating atmosphere can be referred to as an “airborne molecular contaminant sensor” or “AMC sensor,” which includes a volatile organic compound sensor (“VOC sensor”). Other sensors include temperature sensors, pressure sensors, relative humidity sensors, flow sensors to measure a rate of flow of a clean decontaminating gas, effluent, or decontaminating atmosphere that passes into, through, or from the apparatus interior as effluent.

The process control system can work with one or more operating mechanisms that control: movement (opening and closing) of access ports, movement of conveyors to move substrate containers between the apparatus interior and the apparatus exterior and within the apparatus interior, components of a circulation system that control fluid flows (e.g., a flow of clean decontaminating gas, decontaminating atmosphere, or effluent), and other steps of operating the decontamination apparatus.

The control system and sensors can be used to measure, monitor, and control one or more of: a concentration of one or more contaminants (e.g., volatile organic compounds, airborne molecular contaminant, particle contaminants) in a decontaminating atmosphere; temperature of a decontaminating atmosphere, clean decontaminating gas, effluent, or substrate container; relative humidity of a decontaminating atmosphere; or a flow of a fluid (clean decontaminating gas, decontaminating atmosphere, or effluent); each in cooperation with at least a computerized hardware processor with a memory device that is operatively connected to the processor. The memory device can store instructions to be executed by the processor, optionally in response to values measured at one or more sensors, including the AMC sensor. According to various example decontamination systems, a control system can include, as a computer processor, a microprocessor of any form, e.g., a process logic controller (PLC controller) embodied in an application-specific integrated circuit (ASIC), or the like.

In example systems, one or more sensors can be positioned relative to an apparatus interior at locations that are effective to measure a concentration of one or more airborne molecular contaminants (e.g., volatile organic compounds) within a decontaminating atmosphere, clean decontaminating gas, or effluent, of a decontamination process, as well as temperature, pressure, or relative humidity of a decontaminating atmosphere, clean decontaminating gas, or effluent. Sensors may be at an apparatus interior, at an inlet, at an outlet, or at any other effective location. The process control system can receive one or more measured values from the sensors and use that information to adjust or maintain a desired condition of a decontaminating atmosphere or decontamination process.

To maintain a desired concentration of contaminants (e.g., airborne molecular contaminants, e.g., volatile organic compounds) in a decontaminating atmosphere, a control system may monitor and adjust the concentration in response to one or more measured concentration values. To reduce a concentration of one or more contaminants in a decontaminating atmosphere, an amount of clean decontaminating gas may be added to the apparatus interior while an amount of decontaminating atmosphere is removed from the apparatus interior as effluent. The amount of clean decontaminating gas that is added and the amount of effluent that is removed may be controlled to maintain a relatively stable pressure at the apparatus interior. Additionally or alternately, a desired concentration of one or more contaminants in a decontaminating atmosphere may be controlled by the use of a contaminant removal device that continuously or intermittently removes one or more contaminants from a decontaminating atmosphere in an apparatus interior.

The control system may additionally or alternately monitor and control the pressure of a decontaminating atmosphere at the apparatus interior. The control system may monitor the pressure and control the pressure by any of: a vacuum system to remove decontaminating atmosphere from the apparatus interior, a flow of decontaminating gas from the apparatus interior as effluent, and a flow of clean decontaminating gas into the apparatus interior.

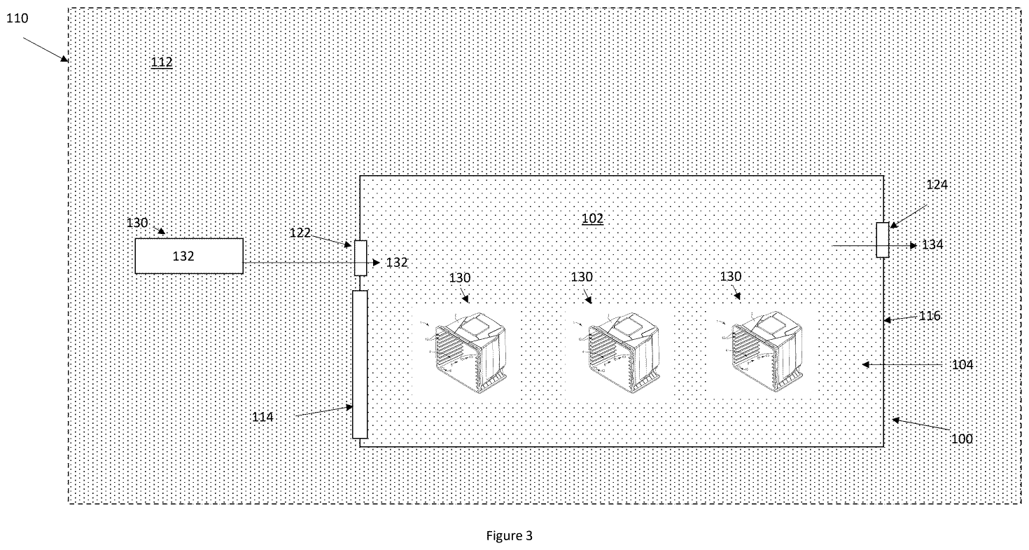

FIG. 3 shows an example of a decontamination apparatus as described and including features also shown and described with respect to FIG. 2. Decontamination apparatus 100 includes enclosure 116 that includes a top, a bottom, and sidewalls that enclose apparatus interior 104 that contains decontaminating atmosphere 102. Decontamination apparatus 100 is housed in apparatus exterior 110, which contains exterior atmosphere 112. Access port 114 is an opening in a sidewall of apparatus 100 that can be opened and closed to allow substrate container 130 to be moved between exterior atmosphere 112 of apparatus exterior 110 and apparatus interior 104.

Apparatus 100 includes source 130 of clean decontaminating gas 132, which can be continuously or intermittently introduced through inlet 122 into apparatus interior 102. Apparatus 100 also includes outlet 124 that allows decontaminating atmosphere 102 to be continuously or intermittently removed from apparatus interior apparatus interior 102 as effluent 134.

During use, decontamination processes can be performed on multiple substrate containers 130 by first moving a substrate container 130 into decontaminating atmosphere 102 at apparatus interior 104, from exterior 110 and exterior atmosphere 112. The substrate container 130 is then held within decontaminating atmosphere 102 during a decontamination period and an optional storage period, and subsequently removed through access port 114 or another access port (not shown). During these steps of the decontamination process, the concentration of airborne molecular contaminants in decontaminating atmosphere 102 is held at a level that will cause adsorbed contaminants to be removed from material of substrate container 130 and pass into decontaminating atmosphere 102. Also during these steps of the decontamination process, the pressure of decontaminating atmosphere 102 at apparatus interior 104 can be held at a pressure that is greater than a low vacuum pressure and that may be a relatively stable pressure as described herein.

As contaminants are removed from substrate container 130, the contaminants transfer into decontaminating atmosphere 102 and the concentration of contaminants (e.g., volatile organic compounds) in decontaminating atmosphere 102 will accordingly increase. To maintain a desired low concentration of contaminants (e.g., volatile organic compounds) in decontaminating atmosphere 102, an amount of the decontaminating atmosphere 102 can be continuously or intermittently removed through outlet 124 as effluent 134. An amount of clean decontaminating gas 132 can also be continuously or intermittently added to apparatus interior 104 from source 130 through inlet 122.

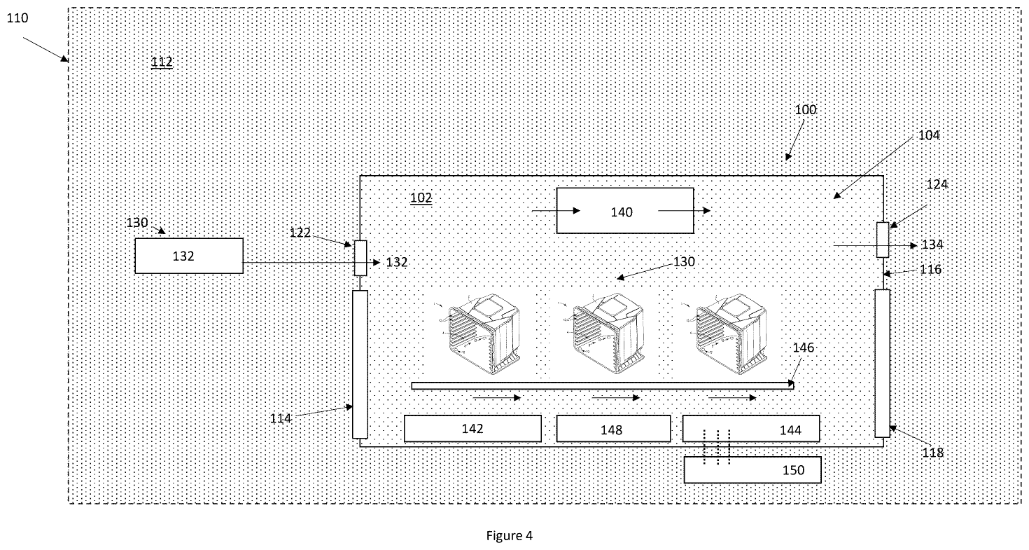

FIG. 4 shows another example of a decontamination apparatus as described. Decontamination apparatus 100 of FIG. 4 is similar to decontamination apparatus 100 of FIG. 3 but additionally includes one or more optional devices or features as described.

For example, decontamination apparatus 100 of FIG. 4 includes contaminant removal device 140, which may be an adsorbent, oxidizer, particle filter or another type of contaminant removal device, or a combination of two or more of these, useful to remove particle contaminants, airborne molecular contaminants, volatile organic compounds, or two or more of these. Device 140 includes an inlet (not shown) through which decontaminating atmosphere 102 from apparatus interior 104 enters device 140, and an outlet (not shown) through which decontaminating atmosphere exits device 140 as clean decontaminating gas having a reduced concentration of contaminants. A flow control device (e.g., a pump, fan, or the like) can be included to cause the decontaminating atmosphere in apparatus interior 104 to flow through contaminant removal device 140 and return to apparatus interior 104 as clean decontaminating gas (see arrows).

Decontamination apparatus 100 of FIG. 4 also includes one or more different types of sensors 144, which are part of or are connected electronically to control system 150. Sensors 144 may include one or more of: a sensor that measures a concentration of particle contaminants, airborne molecular contaminants, or volatile organic compounds in decontaminating atmosphere 102; a sensor that measures the pressure of decontaminating atmosphere 102 in apparatus interior 104; a sensor that measures relative humidity of decontaminating atmosphere 102 in apparatus interior 104; a sensor that measures a temperature of decontaminating atmosphere 102 or of one or more substrate containers 130; or a flow sensor that measures a flow of decontaminating atmosphere 102 within apparatus interior 102 or a flow of clean decontaminating gas into apparatus interior 102 or a flow of effluent from apparatus interior 102. An individual sensor of sensors 140 can be located at any location within apparatus interior 102 that will be effective to perform a sensing (measurement) function.

Heater 148 can be used to heat one or more of substrate containers 130 or decontaminating atmosphere 102. Conveyor 146 can be used to move one or more substrate containers 130 within apparatus interior 104. Conveyor 146 is a horizontal conveyor, but apparatus 100 may alternately or additionally include a vertical conveyor to move substrates vertically within apparatus interior 102. As illustrated, apparatus 100 includes a second access port 118 and multiple substrate containers 130 moving within apparatus interior 102.

During an example decontamination process, substrate containers 130 are moved from exterior 110 through access port 114 and into apparatus interior 102 while the pressure of decontaminating atmosphere 102 in interior 104 is held at a pressure above a low vacuum pressure (e.g., 1 millibar), which may be relatively stable. Each substrate container is moved individually through access port 114 and subsequently moved by conveyor 146. Each substrate container is held at interior 104 for a decontamination period and an optional storage period. With substrate containers held in apparatus interior 104, and as substrate containers 130 are moved through access port 114 or 118, the pressure of decontaminating gas 102 in apparatus interior 104 is maintained above a low vacuum level, which may be at a relatively stable pressure. A concentration of contaminants and the pressure of decontaminating atmosphere 102 in apparatus interior 104 can be controlled by continuously or intermittently adding clean decontaminating gas 132 through inlet 122 and by continuously or intermittently removing effluent 134 through outlet 124.

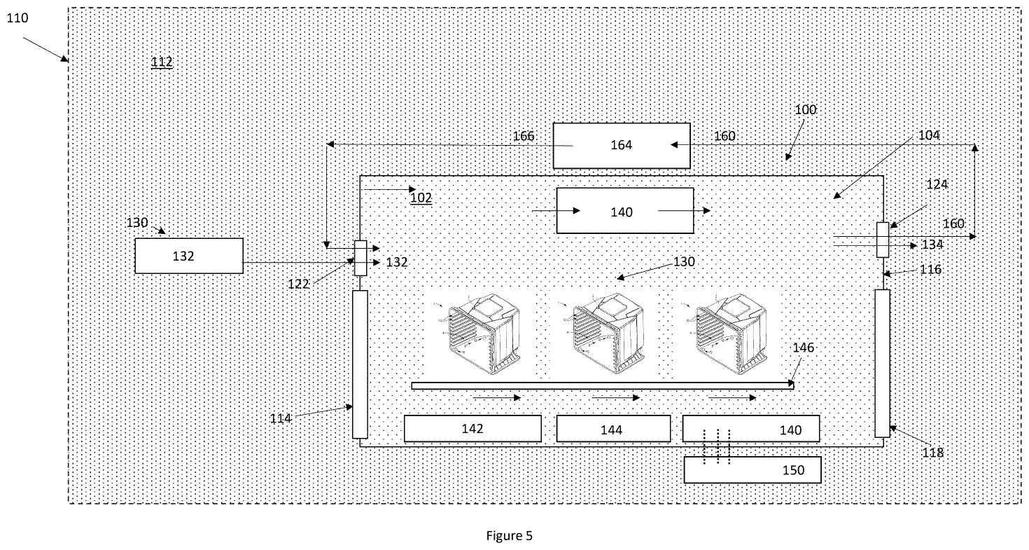

FIG. 5 shows another example of a decontamination apparatus as described. Decontamination apparatus 100 of FIG. 5 is similar to decontamination apparatus 100 of FIG. 4 but is adapted to produce a recycled decontaminating gas 166 by processing a recycle effluent 160 using contaminant removal device 164, external to apparatus interior 104.

In use, recycle effluent 160 is removed from apparatus interior 104 and flows into contaminant removal device 164, which may be the same or different compared to contaminant removal device 140. Recycle effluent 160 passes through contaminant removal device 164, where one or more particle contaminants or chemical contaminants (e.g., airborne molecular contaminants such as volatile organic compounds) are removed from recycle effluent 160, to produce recycled decontaminating gas 166, which is a type of clean decontaminating gas that can then be added back to apparatus interior 104.

Aspect 1. A method of decontaminating a substrate container, the method comprising:
in a decontamination apparatus that comprises:
   an enclosure that defines an apparatus interior,
   an access port that connects the apparatus interior to an exterior atmosphere, and
   decontaminating atmosphere in the apparatus interior,
   moving a substrate container from the apparatus exterior, through the access port, and into the decontaminating atmosphere, the substrate container comprising a body that contains adsorbed contaminants, the decontaminating atmosphere causing the absorbed contaminants to desorb from the body at a rate that is faster than a rate at which the adsorbed contaminants desorb from the body when held in the exterior atmosphere.

Aspect 2. The method of aspect 1, the decontaminating atmosphere containing a concentration of one or more airborne molecular contaminants that is less than a concentration of the one or more airborne molecular contaminants in the exterior atmosphere.

Aspect 3. The method of aspect 1, the decontaminating atmosphere having concentration below 100 parts per billion of one or more airborne molecular contaminants.

Aspect 4. The method of aspect 1, the decontaminating atmosphere having a pressure at the apparatus interior that is at least 1 millibar.

Aspect 5. The method of aspect 1, the decontaminating atmosphere having a temperature in a range from 32 to 100 degrees Celsius.

Aspect 6. The method of aspect 1, the decontaminating atmosphere having a relative humidity in a range from 10 to 80 percent.

Aspect 7. The method of aspect 1, the body defining an interior comprising an interior surface and an exterior comprising an exterior surface, the method comprising holding the substrate container in the decontaminating atmosphere to allow the decontaminating atmosphere to contact the interior surface and the exterior surface.

Aspect 8. The method of aspect 1, comprising:
holding the substrate container in the apparatus interior to cause adsorbed contaminants to desorb from the body into the decontaminating atmosphere,
removing the substrate container from the apparatus interior, and
during a decontamination process that includes moving the substrate container into the apparatus interior, an entire time of holding the substrate container in the apparatus interior, and removing the substrate container from the apparatus interior, maintaining a pressure of the decontaminating atmosphere above 1 millibar.

Aspect 9. The method of aspect 8, comprising maintaining the pressure of the decontaminating atmosphere above 100 millibar during the decontamination period.

Aspect 10. The method of aspect 1, wherein during moving the substrate container from the exterior atmosphere through the access port and into the apparatus interior, maintaining a pressure of the decontaminating gas in the apparatus interior in a range that does not vary by more than 0.1 atmosphere.

Aspect 11. The method of aspect 1, wherein the decontamination apparatus comprises an inlet adapted to deliver clean decontaminating gas to the apparatus interior and an outlet adapted to remove effluent from the apparatus interior, the method comprising:
continuously or intermittently adding clean decontaminating gas into the apparatus interior, and
continuously or intermittently removing effluent from the apparatus interior.

Aspect 12. The method of aspect 11, wherein the clean decontaminating gas is selected from: clean dry air, purified air, and filtered effluent.

Aspect 13. The method of aspect 1, comprising:
moving the substrate container vertically or horizontally within the apparatus interior.

Aspect 14. The method of aspect 13, comprising
moving the substrate container into the decontaminating atmosphere through the access port,
moving the substrate container vertically or horizontally within the apparatus interior, and
removing the substrate container from the apparatus interior through the access port.

Aspect 15. The method of aspect 13, comprising
moving the substrate container into the apparatus interior through the access port,
moving the substrate container vertically or horizontally within the apparatus interior, and
   removing the substrate container from the apparatus interior through a second access port.

Aspect 16. The method of aspect 1, comprising, with three or more substrate containers located in the apparatus interior:
removing a first substrate container from the apparatus interior, and
moving a second substrate container from the apparatus exterior into the decontaminating atmosphere.

Aspect 17. The method of aspect 1, comprising with five or more substrate containers located in the apparatus interior:
removing a first substrate container from the apparatus interior, and
moving a second substrate container from the apparatus exterior into the decontaminating atmosphere.

Aspect 18. The method of aspect 1, wherein adsorbed volatile organic compound comprises: monomer, dimer, oligomer, plasticizer, organic solvent, metal ion, or a combination of two or more of these.

Aspect 19. The method of aspect 1, wherein the adsorbed volatile organic compound comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

Aspect 20. A decontamination apparatus for decontaminating a substrate container, the decontamination apparatus comprising:
an enclosure that defines an apparatus interior,
an access port that connects the apparatus interior to an exterior atmosphere, and
decontaminating atmosphere in the apparatus interior, the decontaminating atmosphere being capable of causing adsorbed contaminant present in a material of a substrate container to desorb from the material at a rate that is faster than a rate at which the adsorbed contaminant desorbs from the material when held in the exterior atmosphere,
   the access port adapted to allow a substrate container to be moved between the exterior atmosphere and the decontaminating atmosphere.

Aspect 21. The decontamination apparatus of aspect 20, comprising a circulation system adapted to:
deliver clean decontaminating gas into the apparatus interior through an inlet,
remove decontaminating atmosphere from the apparatus interior through an outlet.

Aspect 22. The decontamination apparatus of aspects 21, the circulation system being capable of maintaining a concentration of airborne molecular contaminants in the decontaminating atmosphere below a concentration of airborne molecular contaminants in the exterior atmosphere.

Aspect 23. The decontamination apparatus of aspects 21 the circulation system comprising a filter adapted to remove one or more contaminants from the decontaminating atmosphere, wherein gaseous atmosphere that is removed from the interior is passed through the filter and returned to the apparatus interior through the inlet.

Aspect 24. The decontamination apparatus of any of aspects 20 through 23, comprising a heating device to heat the decontaminating atmosphere.

Aspect 25. The decontamination apparatus of any of aspects 20 through 23, wherein a positive pressure is maintained at the access port relative to the exterior atmosphere to cause decontaminating atmosphere to flow through the access port from the apparatus interior to the apparatus exterior.

Aspect 26. The decontamination apparatus of any of aspects 20 through 23, wherein the access port comprises an air lock.

Aspect 27. The decontamination apparatus of any of aspects 20 through 26, comprising: a horizontal conveyor to move the substrate container horizontally within the apparatus interior, a vertical conveyor to move the substrate container vertically within the apparatus interior, or both.

Aspect 28. The decontamination apparatus of any of aspects 20 through 27, comprising:
a first access port adapted to allow movement of a substrate container between the apparatus interior and the apparatus exterior at a first location of the conveyor, and
a second access port adapted to allow movement of a substrate container between the apparatus interior and the apparatus exterior at a second location of the conveyor.

Aspect 29. The decontamination apparatus of any of aspects 20 through 27, wherein the decontaminating atmosphere comprises a measured value of less than 200 parts per billion of one or more airborne molecular contaminants.

Aspect 30. The decontamination apparatus of any of aspects 20 through 39, comprising a humidity control system that controls a humidity of the decontaminating atmosphere.

Aspect 31. The decontamination apparatus of any of aspects 20 through 30, comprising a sensor to detect a concentration of volatile organic compound within the gaseous purification atmosphere.

Aspect 32. The decontamination apparatus of any of aspects 20 through 32, adapted to contain more than four substrate containers.

Aspect 33. The decontamination apparatus of any of aspects 20 through 32, adapted to contain more than ten substrate containers.

1. A method of decontaminating a substrate container, the method comprising:
in a decontamination apparatus that comprises:
an enclosure that defines an apparatus interior,
an access port that connects the apparatus interior to an exterior atmosphere, and
decontaminating atmosphere in the apparatus interior,
moving a substrate container from the apparatus exterior, through the access port, and into the decontaminating atmosphere, the substrate container comprising a body that contains adsorbed contaminants, the decontaminating atmosphere causing the absorbed contaminants to desorb from the body at a rate that is faster than a rate at which the adsorbed contaminants desorb from the body when held in the exterior atmosphere.

2. The method of claim 1, the decontaminating atmosphere containing a concentration of one or more airborne molecular contaminants that is less than a concentration of the one or more airborne molecular contaminants in the exterior atmosphere.

3. The method of claim 1, the decontaminating atmosphere having concentration below 100 parts per billion of one or more airborne molecular contaminants.

4. The method of claim 1, the decontaminating atmosphere having a pressure at the apparatus interior that is at least 1 millibar.

5. The method of claim 1, the decontaminating atmosphere having a temperature in a range from 32 to 100 degrees Celsius.

6. The method of claim 1, the decontaminating atmosphere having a relative humidity in a range from 10 to 80 percent.

7. The method of claim 1, the body defining an interior comprising an interior surface and an exterior comprising an exterior surface, the method comprising holding the substrate container in the decontaminating atmosphere to allow the decontaminating atmosphere to contact the interior surface and the exterior surface.

8. The method of claim 1, comprising:
holding the substrate container in the apparatus interior to cause adsorbed contaminants to desorb from the body into the decontaminating atmosphere,
removing the substrate container from the apparatus interior, and
during a decontamination process that includes moving the substrate container into the apparatus interior, an entire time of holding the substrate container in the apparatus interior, and removing the substrate container from the apparatus interior, maintaining a pressure of the decontaminating atmosphere above 1 millibar.

9. The method of claim 8, comprising maintaining the pressure of the decontaminating atmosphere above 100 millibar during the decontamination period.

10. The method of claim 1, wherein during moving the substrate container from the exterior atmosphere through the access port and into the apparatus interior, maintaining a pressure of the decontaminating gas in the apparatus interior in a range that does not vary by more than 0.1 atmosphere.

11. The method of claim 1, wherein the decontamination apparatus comprises an inlet adapted to deliver clean decontaminating gas to the apparatus interior and an outlet adapted to remove effluent from the apparatus interior, the method comprising:
continuously or intermittently adding clean decontaminating gas into the apparatus interior, and
continuously or intermittently removing effluent from the apparatus interior.

12. The method of claim 11, wherein the clean decontaminating gas is selected from: clean dry air, purified air, and filtered effluent.

13. The method of claim 1, comprising:
moving the substrate container vertically or horizontally within the apparatus interior.

14. The method of claim 13, comprising
moving the substrate container into the decontaminating atmosphere through the access port,
moving the substrate container vertically or horizontally within the apparatus interior, and
removing the substrate container from the apparatus interior through the access port.

15. The method of claim 13, comprising
moving the substrate container into the apparatus interior through the access port,
moving the substrate container vertically or horizontally within the apparatus interior, and
removing the substrate container from the apparatus interior through a second access port.

16. The method of claim 1, comprising, with three or more substrate containers located in the apparatus interior:
removing a first substrate container from the apparatus interior, and
moving a second substrate container from the apparatus exterior into the decontaminating atmosphere.

17. The method of claim 1, comprising with five or more substrate containers located in the apparatus interior:
removing a first substrate container from the apparatus interior, and
moving a second substrate container from the apparatus exterior into the decontaminating atmosphere.

18. The method of claim 1, wherein adsorbed volatile organic compound comprises: monomer, dimer, oligomer, plasticizer, organic solvent, metal ion, or a combination of two or more of these.

19. The method of claim 1, wherein the adsorbed volatile organic compound comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.
